(19) United States
(12) Patent Application Publication
(10) Pub. No.: US 2026/0343836 A1
(43) Pub. Date: Oct. 29, 2026

(54) POWER MODULE UNIT

(71) Applicant: HYUNDAI MOBIS CO., LTD., Seoul (KR)

(72) Inventor: Keun Jae LEE, Yongin-si (KR)

(73) Assignee: HYUNDAI MOBIS CO., LTD., Seoul (KR)

(21) Appl. No.: 19/432,733

(22) Filed: Dec. 24, 2025

(30) Foreign Application Priority Data
Apr. 25, 2025 (KR) 10-2025-0054308

(51) Int. Cl. H05K 7/20; B60L 3/00; H02M 1/08; H02M 1/32

(52) U.S. Cl. CPC H05K 7/20945; H02M 1/08; H02M 1/327; H05K 7/209; H05K 7/20927; B60L 3/003; B60L 2240/525

(57) ABSTRACT

Disclosed is a power module unit. According to one or more embodiments of the disclosure, either a single-sided or double-sided cooling method is applied based on a power conversion switching device, thereby promoting heat exchange with a cooling fluid and ensuring stable operation.

### CROSS REFERENCE TO RELATED APPLICATION

The present application claims priority from and the benefit of Korean Patent Application No. 10-2025-0054308, filed on Apr. 25, 2025, the entire content of which is incorporated herein for all purposes by this reference.

### BACKGROUND

### Field

The disclosure relates to a power module unit for stable cooling of a power conversion switching device.

### Description of the Related Art

Due to regulations on global environmental pollution and policies for energy efficiency, interest in eco-friendly vehicles or eco-friendly power generation and transmission of solar, wind, and others has recently been growing significantly. In particular, power module units used in the eco-friendly vehicles such as hybrid electric vehicles (HEV), electric vehicles (EV), and fuel cell electric vehicles (FCEVs) are required to have high reliability under more severe conditions because they operate at higher temperature and for longer durations compared to general electronic products.

In addition, as the demand for high-temperature electronics increases in applications such as thermoelectric device packaging and aerospace electronic components, there is a growing need for reliable semiconductor bonding materials and bonding process technologies that can ensure stable operation even under high-temperature conditions.

A representative semiconductor module in high-temperature bonding applications is a power module unit, which is used for power conversion or high-power transmission. The power module unit includes a power semiconductor, a die-attach material, a ceramic substrate or lead-frame, an interconnection material, and a molding and casing material. Recently, research and development have been actively conducted to meet the demands for miniaturization, higher operating voltages, and high-density integration.

For example, a power semiconductor device is installed in a power module unit, and is cooled by a heat sink provided in the power module unit.

A conventional heat sink for the power module unit will be described with reference to the accompanying drawing.

Referring to FIG. 1, a conventional power module unit includes a heat transfer substrate 3 formed on an upper surface of an insulator 2, and a heat sink 6 formed on a lower surface of the insulator 2.

Further, a power conversion switching device 4 is disposed on an upper surface of the heat transfer substrate 3, and the heat sink 6 is formed with a channel section 6a including a plurality of channels through which a cooling fluid flows.

The cooling fluid is cooled through heat exchange with high-temperature heat transferred from the power conversion switching device 4 while flowing along the channel section 6a, and a housing 10 is provided surrounding the heat sink 6.

The conventional heat sink 6 has limitations in thickness, thereby making it difficult to design various channel sections 6a that meet specific conditions. In this case, a high pressure loss occurs when the cooling is performed through the heat exchange with the cooling fluid flowing via the channel section 6a.

When the pressure loss caused by the flow of the cooling fluid in the channel section 6a is high, a higher output from a cooling fluid pump provided in a vehicle is required, thereby leading to an issue of increasing the vehicle's overall energy consumption. Accordingly, a countermeasure for this issue has become necessary.

### SUMMARY

An aspect of the disclosure is to provide a power module unit that provides stable cooling performance for a power conversion switching device or a component that generates heat at high temperatures.

In one general aspect, a power module unit includes a power conversion switching device; a heat sink formed with a first fluid channel section configured to receive thermal energy generated from the power conversion switching device and perform heat exchange with a cooling fluid; and a power module housing formed with a second fluid channel section at a position facing the first fluid channel section.

The first fluid channel section and the second fluid channel section may be formed with a same internal surface area.

The first fluid channel section and the second fluid channel section may be formed with different internal surface areas.

The first fluid channel section and the second fluid channel section may be formed with different cross-sectional shapes.

The first fluid channel section may include first unit fluid channels arranged below the power conversion switching device; second unit fluid channels arranged at one lateral side of the first unit fluid channels; and third unit fluid channels arranged at an other lateral side of the first unit fluid channels.

The second fluid channel section may include fourth unit fluid channels forming passages, through which a cooling fluid flows, together with the first unit fluid channels; fifth unit fluid channels arranged at one lateral side of the fourth unit fluid channels and forming passages, through which the cooling fluid flows, together with the second unit fluid channels; and sixth unit fluid channels arranged at an other lateral side of the fourth unit fluid channels and forming passages, through which the cooling fluid flows, together with the third unit fluid channels.

The first fluid channel section may include first protrusions spaced apart from each other at predetermined intervals inside the first unit fluid channels and protruding toward the fourth unit fluid channels by a predetermined length; second protrusions spaced apart from each other at predetermined intervals inside the second unit fluid channels and protruding toward the fifth unit fluid channels by a predetermined length; and third protrusions spaced apart from each other at predetermined intervals inside the third unit fluid channels and protruding toward the sixth unit fluid channels by a predetermined length.

The second fluid channel section may include fourth protrusions spaced apart from each other at predetermined intervals inside the fourth unit fluid channels and being in surface contact with extended ends of the first protrusions; fifth protrusions spaced apart from each other at predetermined intervals inside the fifth unit fluid channels and being in surface contact with extended ends of the second protrusions; and sixth protrusions spaced apart from each other at predetermined intervals inside the sixth unit fluid channels and being in surface contact with extended ends of the third protrusions.

The first protrusions may be spaced apart from an inner bottom surface of the second fluid channel section by a predetermined gap.

The fourth unit fluid channels may include lower spaces in communication with each other through the predetermined gap.

Assuming that an extended length of each of the second protrusions is A and an extended length of each of the first protrusions is B, a relationship of B/A ≤2 may be maintained.

In another general aspect, a power module unit includes a power conversion switching device; heat sinks respectively disposed on lower and upper sides of the power conversion switching device, wherein the heat sinks are configured to receive thermal energy generated from the power conversion switching device and perform heat exchange with a cooling fluid, and are formed with a first fluid channel section; and a power module housing formed with a second fluid channel section at a position facing the first fluid channel section, wherein the power conversion switching device is subjected to double-sided cooling on both the lower and upper sides through the heat sinks and the power module housing.

Each of the heat sinks may include a first heat sink provided below the power conversion switching device; and a second heat sink provided above the power conversion switching device, and the first fluid channel section may include first lower unit fluid channels formed in the first heat sink; and first upper unit fluid channels formed in the second heat sink.

The power module housing may include a first power module housing coupled to the first heat sink; and a second power module housing coupled to the second heat sink, and the second fluid channel section may include second lower unit fluid channels formed in the first power module housing and providing passages, through which the cooling fluid flows, together with the first lower unit fluid channels; and second upper unit fluid channels formed in the second power module housing and providing passages, through which the cooling fluid flows, together with the first upper unit fluid channels.

The first lower unit fluid channels and the second lower unit fluid channels may be formed with shapes and surface areas different from the shapes and surface areas of the first upper unit fluid channels and the second upper unit fluid channels.

The first fluid channel section may include first protrusions spaced apart from each other at predetermined intervals inside the first lower unit fluid channels and protruding toward the second lower unit fluid channels by a predetermined length.

The first protrusions may be spaced apart from an inner bottom surface of the first lower unit fluid channels by a predetermined gap.

The fourth unit fluid channels may include lower spaces in communication with each other through the predetermined gap.

The first fluid channel section may be formed with second protrusions and third protrusions extending a predetermined length at one lateral side and an other lateral side of the first lower unit fluid channels, and, assuming that an extended length of each of the second protrusions and each of the third protrusions is A and an extended length of each of the first protrusions is B, a relationship of B/A≤2 may be maintained.

The heat sinks and the power module housing may be alternately stacked N times.

### BRIEF DESCRIPTION OF THE DRAWINGS

FIG. 1 is a cross-sectional view of a conventional power module cooler.

FIG. 2 is a longitudinal cross-sectional perspective view of a power module unit according to an embodiment.

FIG. 3 is a cross-sectional view showing various shapes of first and second fluid channel sections according to an embodiment.

FIG. 4 is a cross-sectional view showing a detailed configuration of a power module unit according to an embodiment.

FIG. 5 is a cross-sectional view showing various configuration shapes of first and second fluid channel sections according to an embodiment.

FIG. 6 is a diagram showing an example in which a gap is formed in a second fluid channel section according to an embodiment.

FIG. 7 is a longitudinal cross-sectional view of a power module unit according to another embodiment of the disclosure.

FIGS. 8 to 10 are cross-sectional views showing arrangement of first and second fluid channel sections according to another embodiment of the disclosure.

FIG. 11 is a diagram showing that a heat sink and a power module housing according to an embodiment are alternately stacked N times.

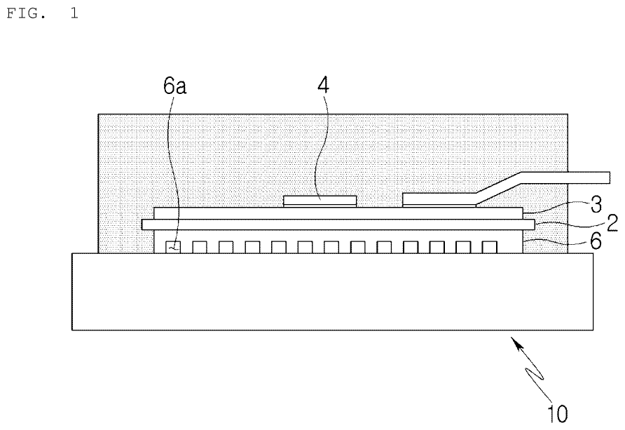

### DETAILED DESCRIPTION

The advantages and features of the disclosure and methods of achieving them will become apparent with reference to the following embodiments described in detail in conjunction with the accompanying drawings. However, the disclosure is not limited to the embodiments set forth herein but may be implemented in various different forms. These embodiments are provided solely to ensure a complete understanding of the disclosure and to fully convey the scope of the disclosure to a person having ordinary knowledge in the art to which the disclosure pertains, and the scope of the disclosure is defined only by the appended claims. Throughout the specification, like reference numerals refer to like elements.

When an element is referred to as being “connected to” or “coupled to” another element, it may be directly connected or coupled to the other element, or connected or coupled to the other element via one or more intervening elements. In contrast, when an element is referred to as being “directly connected to” or “directly coupled to” another element, it means that there are no intervening elements between them. The term “and/or” includes each of the mentioned items as well as any combination of one or more of them.

The terminology used in this specification is for the purpose of describing embodiments only and is not intended to limit the disclosure. In this specification, singular forms include plural forms unless otherwise specified. The terms “comprise” and/or “comprising,” as used in this specification, do not exclude the presence or addition of one or more other elements, steps, operations and/or devices other than the mentioned elements, steps, operations and/or devices.

Although the terms such as “first,” “second,” and the like may be used to describe various elements, it should be understood that these elements are not limited by these terms. These terms are only used to distinguish one element from another element.

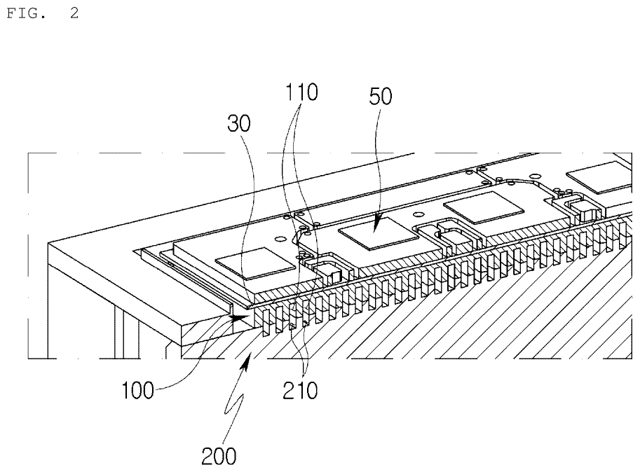

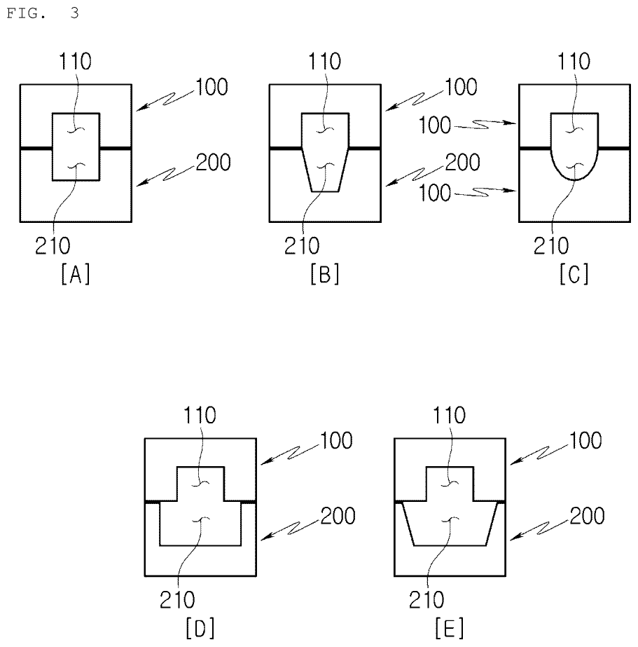

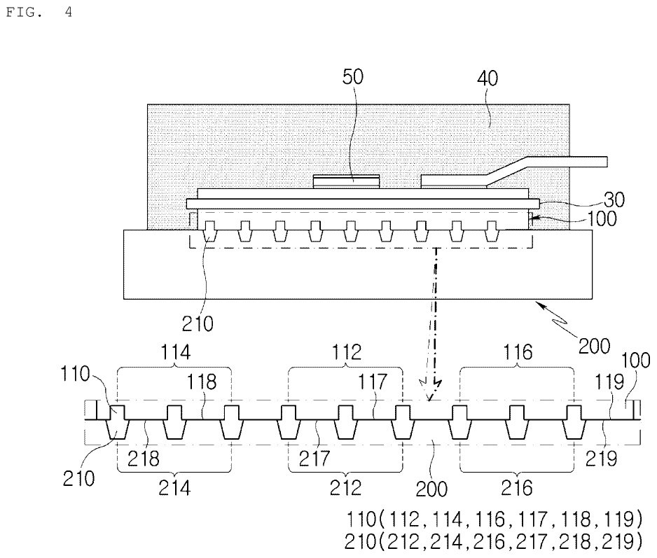

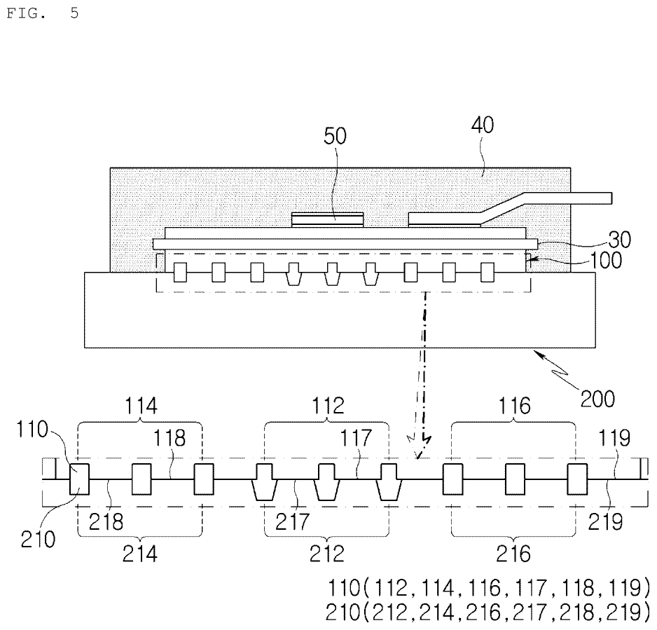

A power module unit according to an embodiment of the disclosure will be described with reference to the accompanying drawings. For reference, FIG. 2 is a longitudinal cross-sectional perspective view of a power module unit according to an embodiment, FIG. 3 is a cross-sectional view showing various shapes of first and second fluid channel sections according to an embodiment, FIG. 4 is a cross-sectional view showing a detailed configuration of the power module unit according to an embodiment, and FIG. 5 is a cross-sectional view showing various configuration shapes of the first and second fluid channel sections according to an embodiment.

Referring to FIGS. 2 to 5, the power module unit according to this embodiment may be configured to cool only a single side of a heat sink 100 positioned adjacent to a power conversion switching device 50, together with a power module housing 200, in order to stably cool the power conversion switching device 50 that operates at a high temperature. For reference, the one side is defined as a lower side in the direction of gravity, in surface contact with the module housing 200, but may vary depending on the installation position.

The reason why this embodiment is configured in this way is to more efficiently cool the power conversion switching device 50 by utilizing the space of the power module housing 200 in consideration of the thickness of the heat sink 100 for cooling the power conversion switching device 50 and the layout with surrounding components.

In this case, the power module unit according to this embodiment includes the power conversion switching device 50, the heat sink 100 formed with a first fluid channel section 110 to exchange heat energy generated from the power conversion switching device 50 with a cooling fluid, and the power module housing 200 formed with a second fluid channel section 210 at a position facing the first fluid channel section 110.

The power module unit includes a first heat transfer substrate formed on an upper surface of the insulator 30, a second heat transfer substrate formed on a lower surface of the insulator 30, and the power conversion switching device 50 provided on an upper surface of the first heat transfer substrate.

The power conversion switching device 50 includes a plurality of semiconductor devices, and the semiconductor devices generate heat at a high temperature of 200 to over 300 degrees during actual operation

The first heat transfer substrate and the second heat transfer substrate are configured to receive high-temperature heat generated from the power conversion switching device section 50 and to perform cooling through the heat sink 100 and the power module housing 200 that are in close contact with the second heat transfer substrate.

An insulated gate bipolar transistor (IGBT) is used as the power conversion switching device 50, but may be replaced by another configuration that generates heat at high temperatures during operation.

According to this embodiment, to cool only one side of the heat sink 100 together with the power module housing 200, a resin layer 40 is formed on an upper surface of the power conversion switching device 50. For example, an epoxy molding compound (EMC) is used as the resin layer 40, and the epoxy molding compound (EMC) contains both a filler and a hardener to maintain a high level of hardness by combining with a printed circuit board (PCB), a lead frame, wires, etc. that constitute the power conversion switching device 50.

With the foregoing configuration according to this embodiment, the cooling is performed through the heat sink 100, which is in close contact with the second heat transfer substrate disposed in the direction of gravity with reference to the accompanying drawings, and the power module housing 200 in order to dissipate the high-temperature thermal energy generated during the operation of the power conversion switching device 50.

To this end, according to this embodiment, the first fluid channel section 110 is formed in the heat sink 100, and the second fluid channel section 210 is formed in the power module housing 200, thereby allowing a cooling fluid to flow through the first fluid channel section 110 and the second fluid channel section 210.

The first fluid channel section 110 and the second fluid channel section 210 may be configured to have the same shape, or be configured to have different cross-sectional shapes. For example, as shown in [A] of FIG. 3, the first fluid channel section 110 and the second fluid channel section 210 may be configured to have the same rectangular shape.

Further, as shown in [B], the first fluid channel section 110 may be configured in a rectangular shape, while the second fluid channel section 210 may be configured in a quadrangular or trapezoidal shape different in size from the first fluid channel section 110.

Further, as shown in [C], the first fluid channel section 110 may be configured in a rectangular shape, while the second fluid channel section 210 may be configured in a semicircular shape.

Further, as shown in [D], the first fluid channel section 110 may be configured in a stepped rectangular shape, while the second fluid channel section 210 may be configured in a rectangular shape larger than that of the first fluid channel section 110.

Further, as shown in [E], the first fluid channel section 110 may be configured in a stepped rectangular shape, while the second fluid channel section 210 may be configured in the form of extending upward.

Besides the aforementioned shapes, the first fluid channel section 110 and the second fluid channel section 210 may have various shapes as long as the internal surface area can be maximized without reducing the contact area with the cooling fluid.

The first fluid channel section 110 and the second fluid channel section 210 may be formed to have the same internal surface area or may be formed to have different internal surface areas. To improve the cooling efficiency of the cooling fluid, the internal surface area of the first fluid channel section 110 may be formed to be larger than the internal surface area of the second fluid channel section 210.

On the other hand, as shown in [D] or [E] of FIG. 3, the internal surface area of the second fluid channel section 210 may be formed to be larger than the internal surface area of the first fluid channel section 110.

The detailed configuration of the first fluid channel section according to this embodiment will be described with reference to the accompanying drawings.

Referring to FIGS. 4 and 5, the first fluid channel section 110 according to this embodiment includes first unit fluid channels 112 arranged below the power conversion switching device 50, second unit fluid channels 114 arranged at one lateral side of the first unit fluid channels 112, and third unit fluid channels 116 arranged at the other lateral side of the first unit fluid channels 112.

The first unit fluid channels 112, the second unit fluid channels 114, and the third unit fluid channels 116 may all be configured to have the same cross-sectional shape or be configured to have different cross-sectional shapes, and may be changed in various ways without being limited to the cross-sectional shapes shown in the accompanying drawings.

Because the power module unit according to this embodiment is based on a single-sided cooling method, the first unit fluid channels 112 disposed below the power conversion switching device 50 may be configured to have a cross-sectional shape different from those of the second unit fluid channels 114 and the third unit fluid channels 116 as shown in FIG. 5.

In addition, the first unit fluid channels 112 may be configured to have an internal surface area larger than those of the second unit fluid channels 114 and the third unit fluid channels 116, so that a large amount of cooling fluid can flow, thereby improving the cooling efficiency based on heat exchange.

Further, the foregoing first and second fluid channel sections 110 and 120 having various cross-sectional shapes shown in FIG. 3 may be used in combination, and may be used in various ways without being limited to the configurations shown in the accompanying drawings.

The second fluid channel section 210 according to this embodiment includes fourth unit fluid channels 212 forming passages, through which a cooling fluid flows, together with the first unit fluid channels 112, fifth unit fluid channels 214 arranged at one lateral side of the fourth unit fluid channels 212 and forming passages, through which the cooling fluid flows, together with the second unit fluid channels 114, and sixth unit fluid channels 216 arranged at the other lateral side of the fourth unit fluid channels 212 and forming passages, through which the cooling fluid flows, together with the third unit fluid channels 116.

The fourth unit fluid channels 212 provide the passages, through which the cooling fluid flows, together with the foregoing first unit fluid channels 112, and the fourth unit fluid channels 212, the fifth unit fluid channels 214, and the sixth unit fluid channels 216 may all be configured to have the same cross-sectional shape or be configured to have different cross-sectional shapes, and may be changed in various ways without being limited to the cross-sectional shapes shown in the accompanying drawings.

Referring to FIG. 5, the power module unit according to this embodiment is based on a single-sided cooling method, and thus the fourth unit fluid channels 212 together with the first unit fluid channels 112 disposed below the power conversion switching device 50 form the passages through which the cooling fluid flows, thereby having the cross-sectional shape different from those of the fifth unit fluid channels 214 and the sixth unit fluid channels 216.

For example, considering the characteristic that high-temperature heat is transferred downward from the power conversion switching device 50, the fourth unit fluid channels 212 together with the first unit fluid channels 112 are configured to have an internal surface area larger than those of the fifth unit fluid channels 214 and the sixth unit fluid channels 216 in order to increase the contact area with the cooling fluid, thereby improving cooling performance.

In this case, according to this embodiment, the internal surface area is enlarged to increase the contact area with the cooling fluid and improve the cooling performance for the power conversion switching device 50 under the same conditions, thereby preventing malfunction and ensuring stable operation of a vehicle even when operating for a long time under high temperature conditions.

The first fluid channel section 110 according to this embodiment further includes first protrusions 117 spaced apart from each other at predetermined intervals inside the first unit fluid channels 112 and protruding toward the fourth unit fluid channels 212 by a predetermined length, second protrusions 118 spaced apart from each other at predetermined intervals inside the second unit fluid channels 114 and protruding toward the fifth unit fluid channels 214 by a predetermined length, and third protrusions 119 spaced apart from each other at predetermined intervals inside the third unit fluid channels 116 and protruding toward the sixth unit fluid channels 216 by a predetermined length.

The first protrusions 117 are formed as shown in the accompanying drawings to partition the neighboring first unit fluid channels 112 in the lateral direction as the first unit fluid channels 112 are formed as above.

The second protrusions 118 are formed to partition the neighboring second unit fluid channels 114 adjacent to the second unit fluid channels 114 in the lateral direction as the second unit fluid channels 114 are formed. Likewise, the third protrusions 119 are also formed to partition the third unit fluid channels 116.

The second fluid channel section 210 according to this embodiment further includes fourth protrusions 217 spaced apart from each other at predetermined intervals inside the fourth unit fluid channels 212 and being in surface contact with the extended ends of the first protrusions 117, fifth protrusions 218 spaced apart from each other at predetermined intervals inside the fifth unit fluid channels 214 and being in surface contact with the extended ends of the second protrusions 118, and sixth protrusions 219 spaced apart from each other at predetermined intervals inside the sixth unit fluid channels 216 and being in surface contact with the extended ends of the third protrusions 119.

The fourth protrusions 217 remain in face-to-face close contact with the foregoing first protrusions 117, the fifth protrusions 218 remain in face-to-face close contact with the second protrusions 118, and the sixth protrusions 219 remains in face-to-face close contact with the third protrusions 119.

With this configuration, the stable flow of the cooling fluid to the first fluid channel section 110 and the second fluid channel section 210 is ensured, and flow instability caused by pressure drop is prevented.

In this embodiment, the internal surface areas of the fourth unit fluid channels 212 may be increased to improve the cooling efficiency for the power conversion switching device 50.

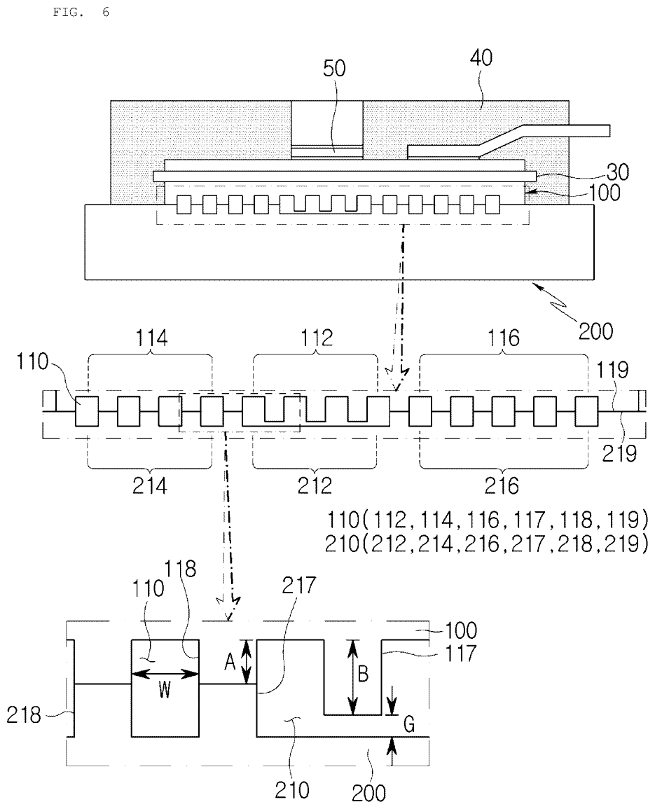

Referring to FIG. 6, the first protrusions 117 according to this embodiment are spaced apart from the inner bottom surface of the second fluid channel section 210 by a predetermined gap G. The gap G is not particularly limited and may be varied in various ways.

In the second fluid channel section 210, lower spaces are in communication with each other through the gap G, and the internal surface area that comes into contact with the cooling fluid flowing through the first unit fluid channels 112 and the fourth unit fluid channels 212 is increased, thereby improving both the cooling rate and efficiency for the power conversion switching device.

In addition, when the fourth unit fluid channels 212 are formed with the gap G, the pressure loss that may occur during the flow of the cooling fluid is reduced, and local cooling efficiency may be improved at the position where the gap G is formed, thereby improving the cooling stability for the power conversion switching device 50.

In this case, the power conversion switching device 50 can be rapidly cooled even when it is momentarily overheated, thereby reducing the likelihood of malfunction and error occurrence, and thus maintaining stable operation of the power conversion switching device.

In this embodiment, assuming that the extended length of the second protrusion 118 is A and the extended length of the first protrusion 117 is B, a relationship of B/A≤2 mm is maintained. The length A of the second protrusion 118 and the extended length B of the first protrusion 117 are configured as above to ensure the safe flow of the cooling fluid and reduce pressure loss.

In this case, pressure drop caused by pressure loss is reduced even when the flow rate of the cooling fluid increases, and the occurrence of vortices or swirling flow during the flow of the cooling fluid is reduced to enable stable fluid flow.

The power module unit according to another embodiment of the disclosure will be described with reference to the accompanying drawings.

Unlike the aforementioned embodiments, heat sinks 1000 according to this embodiment are positioned at the lower and upper sides of the power conversion switching device 50, respectively, so that double-sided cooling can be performed for both the lower and upper surfaces of the power conversion switching device 50. To this end, the outer sides of the heat sinks 1000 are surrounded by a power module housing 2000.

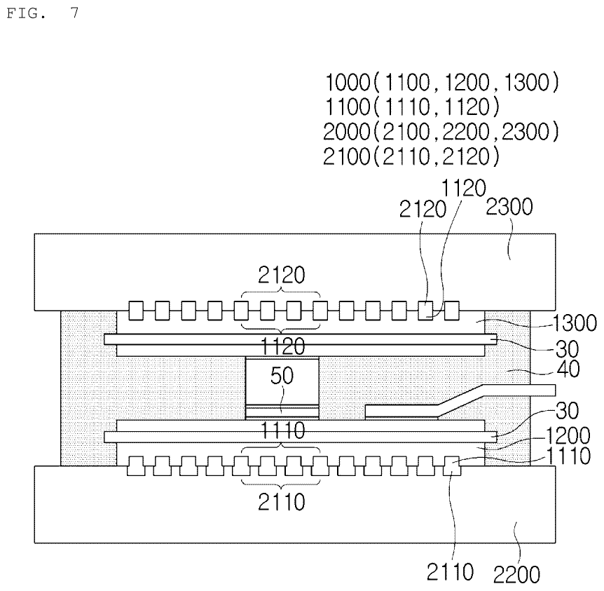

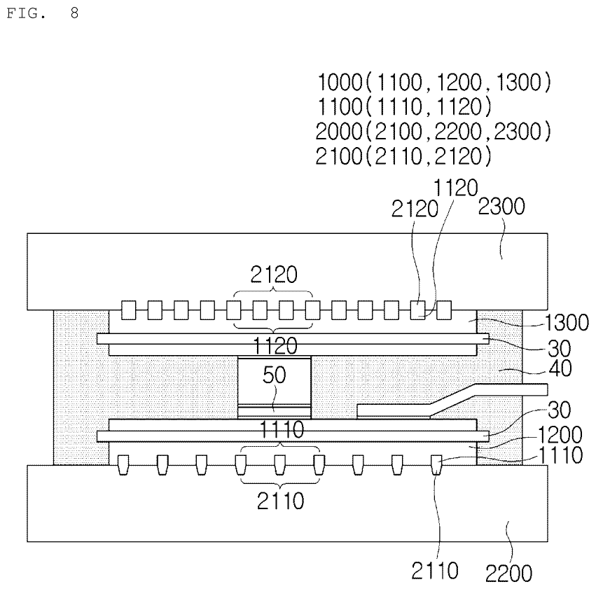

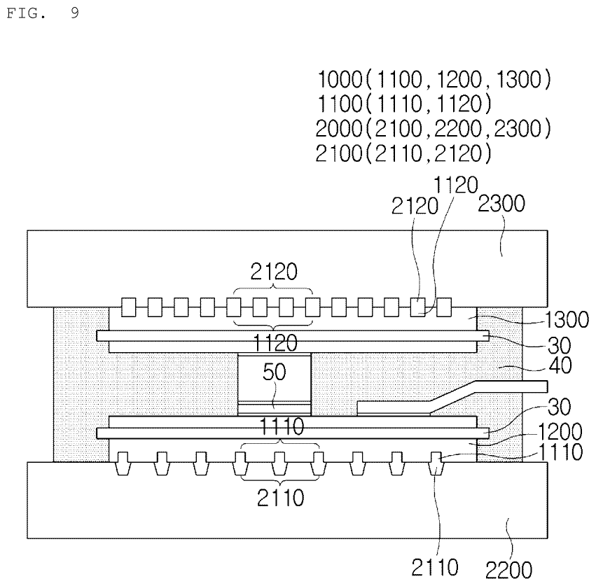

Referring to FIGS. 7 to 9, the power module unit according to this embodiment includes the power conversion switching device 50; the heat sinks 1000 respectively disposed on the lower and upper sides of the power conversion switching device 50 to perform heat exchange between thermal energy generated from the power conversion switching device 50 and the cooling fluid and formed with a first fluid channel section 1100; and the power module housing 2000 formed with a second fluid channel section 2100 formed at a position facing the first fluid channel section 1100, so that the power conversion switching device 50 can be subjected to the double-sided cooling on both the lower and upper sides through the heat sink 1000 and the power module housing 2000.

The reason why this embodiment is configured in this way is to address the limitation in the internal surface area for the cooling fluid due to the thickness of the heat sink 1000 by using both the heat sink 1000 and the power module housing 2000 together for cooling the power conversion switching device 50.

In particular, according to this embodiment, considering the layout to be actually designed as the power module unit becomes smaller, the spaces within the heat sink 1000 and the power module housing 2000 are utilized to configure the first fluid channel section 1100 and the second fluid channel section 2100 through which the cooling fluid can flow.

In this way, when the power conversion switching device 50 is cooled using a double-sided cooling method, the thermal resistance is reduced, thereby enabling stable heat management even when a high-power semiconductor device is used.

In addition, thermal stress does not increase and temperature distribution becomes uniform at specific positions, thereby reducing the deformation of the power conversion switching device 50.

The first fluid channel section 1100 and the second fluid channel section 2100 may be configured to have the same shape or be configured to have different shapes or different cross-sectional shapes. For example, the first fluid channel section 1100 and the second fluid channel section 2100 may be configured to have the same shape, such as a rectangular shape.

The heat sink 1000 according to this embodiment includes a first heat sink 1200 provided below the power conversion switching device 50, and a second heat sink 1300 provided above the power conversion switching device 50. Although the first heat sink 1200 and the second heat sink 1300 are configured to have the same structure, more thermal energy is transferred toward the first heat sink 1200 than toward the second heat sink 1300 while the power conversion switching device 50 operates.

In this case, the first heat sink 1200 may be made of a material with higher thermal conductivity than the second heat sink 1300, or may have a different thickness.

The power module unit includes a first heat transfer substrate formed on an upper surface of the insulator 30, a second heat transfer substrate formed on a lower surface of the insulator 30, and the power conversion switching device 50 provided on an upper surface of the first heat transfer substrate.

The power conversion switching device 50 includes a plurality of semiconductor devices, and the semiconductor devices generate heat at a high temperature of 200 to over 300 degrees during actual operation.

The first heat transfer substrate and the second heat transfer substrate are configured to receive high-temperature heat generated from the power conversion switching device section 50 and to transfer the high-temperature heat toward the lower and upper sides, respectively, based on the accompanying drawings. For example, 60% of the total thermal energy generated in the power conversion switching device 50 is transferred to the lower side where the first heat sink 1200 is located, while 40% is transferred to the upper side where the second heat sink 1300 is located.

According to this embodiment, the double-sided cooling method is implemented to perform the cooling on both sides, i.e., the first heat sink 1200 and the second heat sink 1300 based on such characteristics of the power conversion switching device 50, in which more cooling is carried out on the lower side.

In particular, according to this embodiment, the power module housing 2000 is coupled to the outer sides of the first heat sink 1200 and second heat sink 1300 while allowing the cooling fluid to flow, thereby improving both the cooling performance and efficiency for the power conversion switching device 50.

An insulated gate bipolar transistor (IGBT) is used as the power conversion switching device 50, but may be replaced by another configuration that generates heat at high temperatures during operation

According to this embodiment, a resin layer 40 is formed on the outer side of the power conversion switching device 50, the outer side of the heat sink 1000, and the inner side of the power module housing 2000.

For example, an epoxy molding compound (EMC) is used as the resin layer 40, and the epoxy molding compound (EMC) contains both a filler and a hardener to maintain a high level of hardness by combining with a printed circuit board (PCB), a lead frame, wires, etc. that constitute the power conversion switching device 50.

In addition, the resin layer 40 remains in contact with the outer side of the heat sink 1000 and the inner side of the power module housing 2000, thereby expanding in volume and dissipating thermal energy when the power conversion switching device 50 operates at a high temperature.

The first fluid channel section 1100 according to this embodiment includes first lower unit fluid channels 1110 formed in the first heat sink 1200, and first upper unit fluid channels 1120 formed in the second heat sink 1300.

The first lower unit fluid channel 1110 may be configured identically to the first unit fluid channels 112, the second unit fluid channels 114, and the third unit fluid channels 116 described above, and thus detailed description thereof will be omitted as it has been described above.

The power module housing 2000 includes a first power module housing 2200 coupled to the first heat sink 1200, and a second power module housing 2300 coupled to the second heat sink 1300.

The second fluid channel section 2100 includes second lower unit fluid channels 2110 formed in the first power module housing 2200 and providing passages, through which the cooling fluid flows, together with the first lower unit fluid channels 1110, and second upper unit fluid channels 2120 formed in the second power module housing 2300 and providing passages, through which the cooling fluid flows, together with the first upper unit fluid channels 1120.

The first lower unit fluid channels 1110 and the second lower unit fluid channels 2110 may be formed in a rectangular cross-section shape, but may be formed in various shapes without being limited to the rectangular cross-sectional shape.

The first lower unit fluid channels 1110 and the second lower unit fluid channels 2110 according to this embodiment are formed with shapes and surface areas different from those of the first upper unit fluid channels 1120 and the second upper unit fluid channels 2120.

The first lower unit fluid channels 1110 and the second lower unit fluid channels 2110 may be configured in a stepped or trapezoidal shape, the internal surface area of which is maximized to improve heat transfer efficiency with the cooling fluid, because they receive high-temperature heat generated from the power conversion switching device 50. However, the first lower unit fluid channels 1110 and the second lower unit fluid channels 2110 may be configured in various other shapes considering the layout and thickness of the heat sink 1000 and the power module housing 2000 and enabling the stable flow of the cooling fluid.

In this embodiment, similarly to the aforementioned embodiment, the first lower unit fluid channels 1110 and the second lower unit fluid channels 2110 may be configured in a cross-sectional shape that maximizes the internal surface area. In particular, any one of the cross-sectional shapes shown in the accompanying drawings may be selectively used, taking into account the manufacturable thickness of the first heat sink 1200 and second heat sink 1300.

In this embodiment, the first lower unit fluid channels 1110 and the second lower unit fluid channels 2110 may be formed with different cross-sectional shapes, and their internal surface areas may differ from each other.

Because the internal surface area increases the contact area with the cooling fluid to have a significant effect on improving the cooling performance based on heat transfer, the internal cross-sectional area of the first lower unit fluid channels 1110 may be formed to be larger than the internal cross-sectional area of the second lower unit fluid channels 2110, or the internal cross-sectional area of the second lower unit fluid channels 2110 may be formed to be larger than the internal cross-sectional area of the first lower unit fluid channel 1110.

In this case, according to this embodiment, cooling performance may be improved through heat exchange with the cooling fluid.

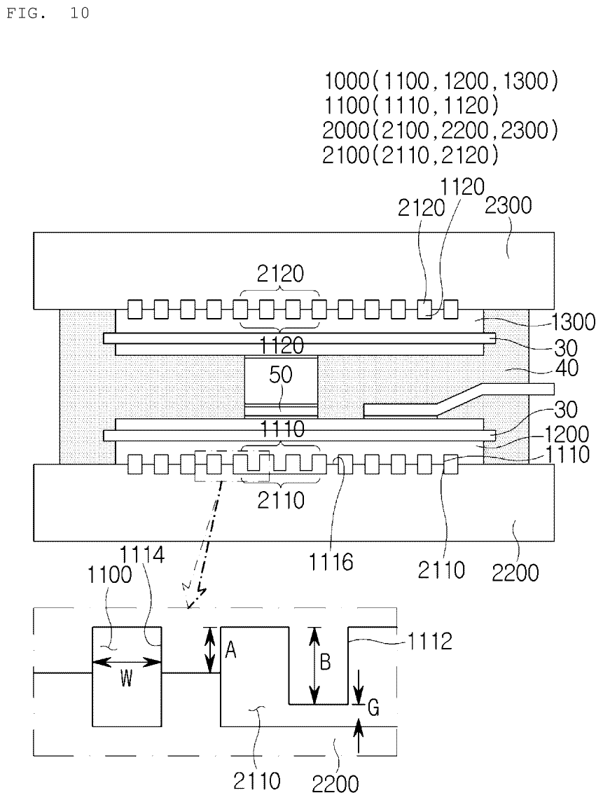

Referring to FIG. 10, the first fluid channel section 1100 further includes first protrusions 1112 spaced apart from each other at predetermined intervals inside the first lower unit fluid channel 1110 and protruding toward the second lower unit fluid channels 2110 by a predetermined length.

The first protrusion 1112 is identical to the configuration described in the aforementioned embodiment, and thus detailed description thereof will be omitted.

The first protrusions 1112 are spaced apart from the inner bottom surface of the first lower unit fluid channel 1110 by a predetermined gap G. The gap G is not particularly limited and may be varied in various ways.

In the second lower unit fluid channel 2110, lower spaces are in communication with each other through the gap G, and the internal surface area that comes into contact with the cooling fluid flowing through the first lower unit fluid channels 1110 and the second lower unit fluid channels 2110 is increased, thereby improving both the cooling rate and efficiency for the power conversion switching device.

In addition, when the second lower unit fluid channels 2110 are formed with the gap G, the pressure loss that may occur during the flow of the cooling fluid is reduced, and local cooling efficiency may be improved at the position where the gap G is formed, thereby improving the cooling stability for the power conversion switching device.

In this case, the power conversion switching device can be rapidly cooled even when it is momentarily overheated, thereby reducing the likelihood of malfunction and error occurrence and thus maintaining stable operation of the power conversion switching device.

The first fluid channel section 1100 is formed with second protrusions 1114 and third protrusions 1116 extending a predetermined length at one lateral side and the other lateral side of the first lower unit fluid channels 1110. Assuming that the extended length of the second and third protrusions 1114 and 1116 is A and the extended length of the first protrusion 1112 is B, a relationship of B/A≤2 mm is maintained.

The length A of the second protrusion 1114 and the extended length B of the first protrusion 1112 are configured as above to ensure the safe flow of the cooling fluid and reduce pressure loss.

In this case, pressure drop caused by pressure loss is reduced even when the flow rate of the cooling fluid increases, and the occurrence of vortices or swirling flow during the flow of the cooling fluid is reduced to enable stable fluid flow.

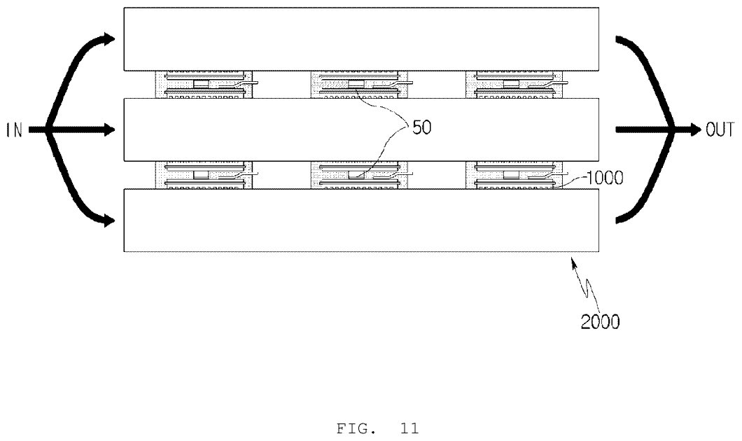

Referring to FIG. 11, the heat sink 1000 and the power module housing 2000 according to this embodiment may be alternately stacked N times. In particular, according to this embodiment, a capacitor or other heat-generating components may be disposed on the upper or lower side of the power conversion switching device 50.

In this case, the cooling fluid is introduced into “IN,” as indicated by the arrow, performs cooling while passing through a plurality of power conversion switching devices or capacitors, and then flows to “OUT.”

Thus, according to this embodiment, additional cooling may be performed for components that operate at high temperatures, such as power conversion switching devices and capacitors, thereby enabling improved space utilization and enhanced cooling performance.

Therefore, the power module unit may be configured to maintain consistent cooling performance even though its interior has a limited layout.

According to the embodiments of the disclosure, the cooling method for the cooling method of the power conversion switching devices arranged inside the power module unit may be selectively applied as either the single-sided cooling method or the double-sided cooling method, thereby improving the cooling performance according to various design configurations of the power module unit.

According to the embodiments of the disclosure, the arrangement, cross-sectional shape, and internal surface area of the fluid channel where the heat exchange with the cooling fluid occurs may be variously applied, thereby improving the cooling efficiency of the power conversion switching device and ensuring stable operation.

According to the embodiments of the disclosure, the arrangement, the fluid channel can be designed with optimal specifications by considering the pressure drop and flow stability that may occur when the cooling fluid flows.

Although a few embodiments of the disclosure have been described above, modifications and changes can be variously made in the disclosure by a person having ordinary knowledge in the art through addition, alteration, deletion or inclusion of components, etc. without departing from the scope of the disclosure defined in the appended claims, and these are also considered to fall within the scope of the disclosure.

### DESCRIPTION OF REFERENCE NUMERALS

50: power conversion switching device
100, 1000: heat sink
110, 1100: first fluid channel section
112: first unit fluid channel
114: second unit fluid channel
116: third unit fluid channel
117: first protrusion
118: second protrusion
119: third protrusion
200, 2000: power module housing
210, 2100: second fluid channel section
212: fourth unit fluid channel
214: fifth unit fluid channel
216: sixth unit fluid channel
217: fourth protrusion
218: fourth protrusion
219: sixth protrusion
1110: first lower unit fluid channel
1112: first protrusion
1114: second protrusion
1116: third protrusion
1120: first upper unit fluid channel
1200: first heat sink
1300: second heat sink
2110: second lower unit fluid channel
2120: second upper unit fluid channel
2200: first power module housing
2300: second power module housing

What is claimed is:

1. A power module unit comprising:
a power conversion switching device;
a heat sink formed with a first fluid channel section configured to receive thermal energy generated from the power conversion switching device and perform heat exchange with a cooling fluid; and
a power module housing formed with a second fluid channel section at a position facing the first fluid channel section.

2. The power module unit of claim 1, wherein the first fluid channel section and the second fluid channel section are formed with a same internal surface area.

3. The power module unit of claim 1, wherein the first fluid channel section and the second fluid channel section are formed with different internal surface areas.

4. The power module unit of claim 1, wherein the first fluid channel section and the second fluid channel section are formed with different cross-sectional shapes.

5. The power module unit of claim 1, wherein the first fluid channel section comprises:
first unit fluid channels arranged below the power conversion switching device;
second unit fluid channels arranged at one lateral side of the first unit fluid channels; and
third unit fluid channels arranged at an other lateral side of the first unit fluid channels.

6. The power module unit of claim 5, wherein the second fluid channel section comprises:
fourth unit fluid channels forming passages, through which a cooling fluid flows, together with the first unit fluid channels;
fifth unit fluid channels arranged at one lateral side of the fourth unit fluid channels and forming passages, through which the cooling fluid flows, together with the second unit fluid channels; and
sixth unit fluid channels arranged at an other lateral side of the fourth unit fluid channels and forming passages, through which the cooling fluid flows, together with the third unit fluid channels.

7. The power module unit of claim 6, wherein the first fluid channel section comprises:
first protrusions spaced apart from each other at predetermined intervals inside the first unit fluid channels and protruding toward the fourth unit fluid channels by a predetermined length;
second protrusions spaced apart from each other at predetermined intervals inside the second unit fluid channels and protruding toward the fifth unit fluid channels by a predetermined length; and
third protrusions spaced apart from each other at predetermined intervals inside the third unit fluid channels and protruding toward the sixth unit fluid channels by a predetermined length.

8. The power module unit of claim 7, wherein the second fluid channel section comprises:
fourth protrusions spaced apart from each other at predetermined intervals inside the fourth unit fluid channels and being in surface contact with extended ends of the first protrusions;
fifth protrusions spaced apart from each other at predetermined intervals inside the fifth unit fluid channels and being in surface contact with extended ends of the second protrusions; and
sixth protrusions spaced apart from each other at predetermined intervals inside the sixth unit fluid channels and being in surface contact with extended ends of the third protrusions.

9. The power module unit of claim 7, wherein the first protrusions are spaced apart from an inner bottom surface of the second fluid channel section by a predetermined gap.

10. The power module unit of claim 9, wherein the fourth unit fluid channels comprise lower spaces in communication with each other through the predetermined gap.

11. The power module unit of claim 7, wherein, assuming that an extended length of each of the second protrusions is A and an extended length of each of the first protrusions is B, a relationship of B/A ≤2 is maintained.

12. A power module unit comprising:
a power conversion switching device;
heat sinks respectively disposed on lower and upper sides of the power conversion switching device, wherein the heat sinks are configured to receive thermal energy generated from the power conversion switching device and perform heat exchange with a cooling fluid, and are formed with a first fluid channel section; and
a power module housing formed with a second fluid channel section at a position facing the first fluid channel section,
wherein the power conversion switching device is subjected to double-sided cooling on both the lower and upper sides through the heat sinks and the power module housing.

13. The power module unit of claim 12, wherein
each of the heat sinks comprises:
a first heat sink provided below the power conversion switching device; and
a second heat sink provided above the power conversion switching device, and
the first fluid channel section comprises:
first lower unit fluid channels formed in the first heat sink; and
first upper unit fluid channels formed in the second heat sink.

14. The power module unit of claim 13, wherein
the power module housing comprises:
a first power module housing coupled to the first heat sink; and
a second power module housing coupled to the second heat sink, and
the second fluid channel section comprises:
second lower unit fluid channels formed in the first power module housing and providing passages, through which the cooling fluid flows, together with the first lower unit fluid channels; and
second upper unit fluid channels formed in the second power module housing and providing passages, through which the cooling fluid flows, together with the first upper unit fluid channels.

15. The power module unit of claim 14, wherein the first lower unit fluid channels and the second lower unit fluid channels are formed with shapes and surface areas different from the shapes and surface areas of the first upper unit fluid channels and the second upper unit fluid channels.

16. The power module unit of claim 14, wherein the first fluid channel section comprises first protrusions spaced apart from each other at predetermined intervals inside the first lower unit fluid channels and protruding toward the second lower unit fluid channels by a predetermined length.

17. The power module unit of claim 16, wherein the first protrusions are spaced apart from an inner bottom surface of the first lower unit fluid channels by a predetermined gap.

18. The power module unit of claim 17, wherein the fourth unit fluid channels comprise lower spaces in communication with each other through the predetermined gap.

19. The power module unit of claim 18, wherein
the first fluid channel section is formed with second protrusions and third protrusions extending a predetermined length at one lateral side and an other lateral side of the first lower unit fluid channels, and, assuming that an extended length of each of the second protrusions and each of the third protrusions is A and an extended length of each of the first protrusions is B, a relationship of B/A ≤2 is maintained.

20. The power module unit of claim 12, wherein the heat sinks and the power module housing are alternately stacked N times.
